(19) United States
(12) Patent Application Publication
(10) Pub. No.: US 2025/0223695 A1
(43) Pub. Date: Jul. 10, 2025

(54) GAS SUPPLY METHOD OF SUBSTRATE PROCESSING APPARATUS

(71) Applicant: JUSUNG ENGINEERING CO., LTD., Gwangju-si (KR)

(72) Inventors: Chul Joo HWANG, Yongin-si (KR); Joo Sung KIM, Yongin-si (KR)

(21) Appl. No.: 18/901,671

(22) Filed: Sep. 30, 2024

(30) Foreign Application Priority Data
Jan. 10, 2024 (KR) 10-2024-0004130

(51) Int. Cl. C23C 16/455; C23C 16/44

(52) U.S. Cl. CPC C23C 16/45525; C23C 16/4408; C23C 16/45561

(57) ABSTRACT

The present inventive concept relates to a gas supply method of a substrate processing apparatus including: a first step of supplying a first source carrier gas from a first source carrier supply unit to a source storage unit to supply a source of the source storage unit to a vaporizer at a certain flow rate through a Mass Flow Controller; a second step of vaporizing the source supplied via the Mass Flow Controller from the source storage unit by using the vaporizer, based on a second source carrier gas supplied from a second source carrier supply unit to the vaporizer; a third step of supplying the source, vaporized by the vaporizer, to the chamber through a second source line; and a fourth step of stopping supply of the source of the source storage unit on the vaporizer and supplying the second source carrier gas to the vaporizer.

### TECHNICAL FIELD

The present inventive concept relates to a gas supply method of a substrate processing apparatus, which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc.

Such a processing process on a substrate may be performed by a substrate processing apparatus. A substrate processing apparatus according to the related art has sequentially injected a first gas and a second gas toward a substrate and has thus performed a processing process on the substrate.

Here, in a case where the first gas has a high viscosity characteristic, the substrate processing apparatus according to the related art has diluted the first gas having high viscosity and has then injected a diluted first gas toward the substrate. In this case, the substrate processing apparatus according to the related art has a problem where a process rate such as a deposition rate decreases by the degree of dilution of the first gas. In a case which injects the first gas toward the substrate in an undiluted state so as to prevent a reduction in deposition rate, the substrate processing apparatus according to the related art is insufficient in amount of supply of the first gas injected toward the substrate because a transfer force which transfers the first gas is insufficient, and due to this, has a problem where the stability of a processing process is reduced, and moreover, it is difficult to secure process reproducibility.

### DISCLOSURE

### Technical Problem

The present inventive concept is devised to solve the above-described problem and is for providing a gas supply method of a substrate processing apparatus which may increase the amount of supply of a high-viscosity source to improve the stability, process reproducibility, and process rate of a processing process.

### Technical Solution

To accomplish the above-described objects, the present inventive concept may include the following elements.

A gas supply method of a substrate processing apparatus according to the present inventive concept may be a method of supplying a gas into a chamber for performing an atomic layer deposition (ALD) process in a substrate processing apparatus including: a first source line connecting a source storage unit, a first source carrier supply unit, a Mass Flow Controller, and a vaporizer with one another, a second source line connecting the vaporizer to the chamber; and a third source line connecting the vaporizer to a second source carrier supply unit and may include: a first step of supplying a first source carrier gas from the first source carrier supply unit to the source storage unit to supply a source of the source storage unit to the vaporizer at a certain flow rate through the Mass Flow Controller; a second step of vaporizing the source supplied via the Mass Flow Controller from the source storage unit by using the vaporizer, based on a second source carrier gas supplied from the second source carrier supply unit to the vaporizer; a third step of supplying the source, vaporized by the vaporizer, to the chamber through the second source line; and a fourth step of stopping supply of the source of the source storage unit on the vaporizer and supplying the second source carrier gas to the vaporizer.

A gas supply method of a substrate processing apparatus according to the present inventive concept may be a method of supplying a gas into a chamber for performing an atomic layer deposition (ALD) process in a substrate processing apparatus including: a first source line connecting a source storage unit, a first source carrier supply unit, a Mass Flow Controller, and a vaporizer with one another, a second source line connected to a first source purge line connected to a first source purge supply unit and connecting the vaporizer to the chamber; a third source line connecting the vaporizer to a second source carrier supply unit; and a third source carrier supply unit connected to the second source line between the vaporizer and the first source purge line and may include: a first step of supplying a first source carrier gas from the first source carrier supply unit to the source storage unit to supply a source of the source storage unit to the vaporizer at a certain flow rate through the Mass Flow Controller; a second step of vaporizing the source supplied via the Mass Flow Controller from the source storage unit by using the vaporizer, based on a second source carrier gas supplied from the second source carrier supply unit to the vaporizer; a third step of supplying the source, vaporized by the vaporizer, to the chamber through the second source line; and a fourth step of stopping supply of the source of the source storage unit on the vaporizer and supplying a third source carrier gas to the second source line between the vaporizer and the first source purge line by using the third source carrier supply unit.

### Advantageous Effect

According to the present inventive concept, the following effects may be realized.

The present inventive concept is implemented to increase a transfer force for supplying a source to a chamber. Accordingly, the present inventive concept may increase the amount of supply of a high-viscosity source, and thus, may contribute to enhance the stability of a processing process. Also, the present inventive concept may decrease a deviation of the amount of supply of the high-viscosity source, and thus, may contribute to enhance process reproducibility.

The present inventive concept may be possible to use the high-viscosity source in the processing process in an undiluted state, and thus, may contribute to enhance a process rate such as a deposition rate.

The present inventive concept is implemented to decrease the amount of loss of the high-viscosity source which is not used in the processing process and is lost. Accordingly, the present inventive concept may contribute to reduce the process cost for performing the processing process.

### DESCRIPTION OF DRAWINGS

FIG. 1 is a schematic configuration diagram of an example of a substrate processing apparatus for performing a gas supply method of a substrate processing apparatus according to the present inventive concept.

FIGS. 2 and 3 are schematic block diagrams of an example of a substrate processing apparatus for performing a gas supply method of a substrate processing apparatus according to the present inventive concept.

FIGS. 4 and 5 are schematic flowcharts of a gas supply method of a substrate processing apparatus according to the present inventive concept.

### MODE FOR INVENTIVE CONCEPT

Hereinafter, an embodiment of a gas supply method of a substrate processing apparatus according to the present inventive concept will be described in detail with reference to the accompanying drawings.

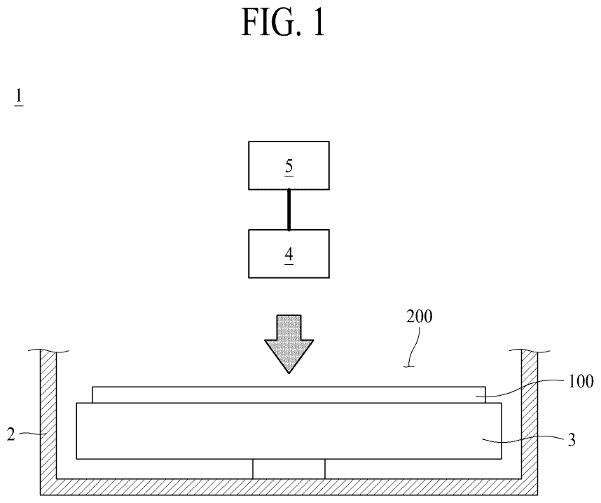

Referring to FIG. 1, the gas supply method of the substrate processing apparatus according to the present inventive concept is for supplying a gas into a chamber 2 where a processing process on a substrate 100 is performed. The substrate 100 may be silicon substrate, a glass substrate, a metal substrate, or the like. The chamber 2 may be included in the substrate processing apparatus 1.

Hereinafter, before describing an embodiment of the gas supply method of the substrate processing apparatus according to the present inventive concept, an example of the substrate processing apparatus 1 according to the present inventive concept will be described in detail with reference to the accompanying drawings.

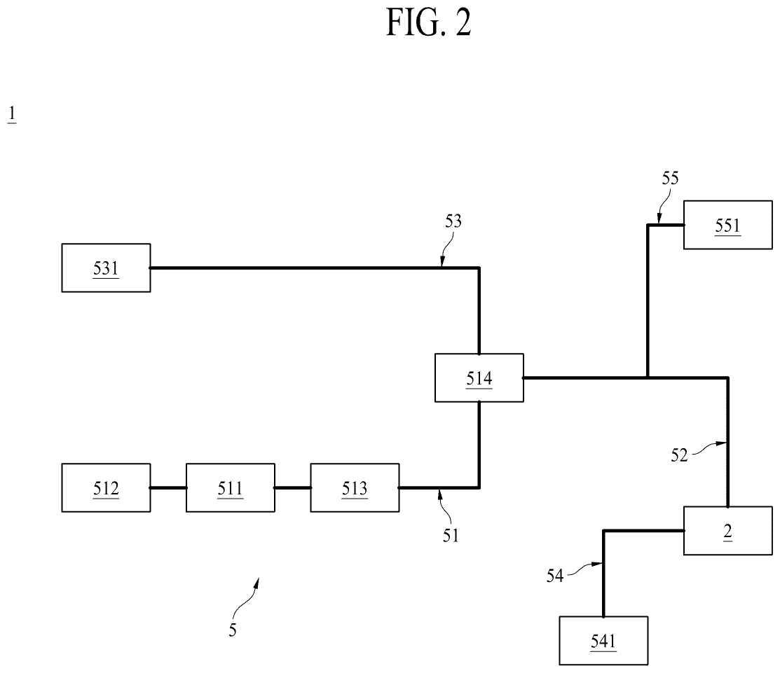

Referring to FIGS. 1 to 3, the substrate processing apparatus 1 may perform an atomic layer deposition (ALD) process to deposit a thin film on the substrate 100. The substrate processing apparatus 1 may include a chamber 2, a substrate supporting unit 3, an injection unit 4, and a supply unit 5.

The chamber 2 may provide a processing space 200. A processing process on the substrate 100 may be performed in the processing space 200. The processing space 200 may be disposed in the chamber 2. An exhaust port (not shown) which exhausts a gas from the processing space 200 may be coupled to the chamber 2. The substrate supporting unit 3 and the injection unit 4 may be disposed in the chamber 2.

The substrate supporting unit 3 supports the substrate 100. The substrate supporting unit 3 may support one substrate 100, or may support a plurality of substrates 100. In a case where the plurality of substrates 100 are supported by the substrate supporting unit 3, a processing process on the plurality of substrates 100 may be performed at a time, and thus, a process of forming a thin film in each of the substrates 100 may be performed. The substrate supporting unit 3 may be coupled to the chamber 2. The substrate supporting unit 3 may be disposed in the chamber 2.

The injection unit 4 injects a gas toward the substrate supporting unit 3. In this case, the injection unit 4 may inject a gas, supplied from the supply unit 5, toward the substrate supporting unit 3. The injection unit 4 may be disposed in the chamber 2. The injection unit 4 may be disposed to be opposite to the substrate supporting unit 3. The injection unit 4 may be disposed on the substrate supporting unit 3. The processing space 200 may be disposed between the injection unit 4 and the substrate supporting unit 3. The injection unit 4 may be coupled to a lid (not shown). The lid may be coupled to the chamber 2 to cover an upper portion of the chamber 2. The injection unit 4 may be connected to a gas supply unit 40. The injection unit 4 may inject a gas toward the substrate supporting unit 3 through a plurality of gas holes (not shown).

The supply unit 5 may supply a gas into the chamber 2. The supply unit 5 may supply a gas to the injection unit 4 and may supply a gas into the chamber 2 through the injection unit 4. The supply unit 5 may include a first source line 51, a second source line 52, and a third source line 53.

The first source line 51 may connect a source storage unit 511, a first source carrier supply unit 512, a Mass Flow Controller 513, and a vaporizer 514 with one another. The first source line 51 may be implemented with a pipe, a hose, or a hole of a gas block. The source storage unit 511 may store a source. The first source carrier supply unit 512 may supply a first source carrier gas. The Mass Flow Controller 513 may adjust a flow rate of the source. The vaporizer 514 may vaporize the source. Each of the source storage unit 511, the first source carrier supply unit 512, the Mass Flow Controller 513, and the vaporizer 514 may be installed in the first source line 51. The source storage unit 511 may be disposed between the first source carrier supply unit 512 and the Mass Flow Controller 513. The Mass Flow Controller 513 may be disposed between the source storage unit 511 and the vaporizer 514. The Mass Flow Controller 513 may be implemented as a liquid mass flow controller (LMFC).

The source stored in the source storage unit 511 may be supplied to the vaporizer 514 through the first source line 51. In this case, when the first source carrier supply unit 512 supplies the first source carrier gas to the source storage unit 511, the first source carrier gas may allow the source stored in the source storage unit 511 to flow to the Mass Flow Controller 513, and a source adjusted at a certain flow rate by the Mass Flow Controller 513 may be supplied to the vaporizer 514.

The second source line 52 may connect the vaporizer 514 to the chamber 2. One side of the second source line 52 may be connected to the vaporizer 514, and the other side may be connected to the injection unit 4 in the chamber 2. Accordingly, a source vaporized by the vaporizer 514 may be supplied into the chamber 2 through the second source line 52. The second source line 52 may be implemented with a pipe, a hose, or a hole of a gas block.

The third source line 53 may connect the vaporizer 514 to the second source carrier supply unit 531. One side of the third source line 53 may be connected to the second source carrier supply unit 531, and the other side may be connected to the vaporizer 514. The third source line 53 may be implemented with a pipe, a hose, or a hole of a gas block. The second source carrier supply unit 531 may supply a second source carrier gas to the vaporizer 514 through the third source line 53. The vaporizer 514 may vaporize the source supplied through the first source line 51 by using the second source carrier gas supplied through the third source line 53. A source vaporized by the vaporizer 514 may be supplied to the chamber 2 through the second source line 52.

The substrate processing apparatus 1 may include a reactant line 54.

The reactant line 54 may connect a reactant supply unit 541 to the chamber 2. One side of the reactant line 54 may be connected to the reactant supply unit 541, and the other side may be connected to the injection unit 4 in the chamber 2. The reactant line 54 may be implemented with a pipe, a hose, or a hole of a gas block. The reactant supply unit 541 may supply a reactant gas to the chamber 2 through the reactant line 54. In this case, the supply unit 5 may alternately supply a source vaporized by the vaporizer 514 and a reactant gas of the reactant supply unit 541 to the chamber 2 via the Mass Flow Controller 513 from the source storage unit 511. Accordingly, a processing process of depositing a thin film on the substrate 100 may be performed by an atomic layer deposition process in the chamber 2.

The substrate processing apparatus 1 may include a first source purge line 55.

The first source purge line 55 may connect the first source purge supply unit 551 to the second source line 52. One side of the first source purge line 55 may be connected to the first source purge supply unit 551, and the other side may be connected to the second source line 52, between the vaporizer 514 and the chamber 2. The first source purge line 55 may be implemented with a pipe, a hose, or a hole of a gas block. The first source purge supply unit 551 may supply a first source purge gas to the second source line 52 through the first source purge line 55. The first source purge gas may be supplied to the second source line 52 and may then flow along the second source line 52 and may be supplied into the chamber 2.

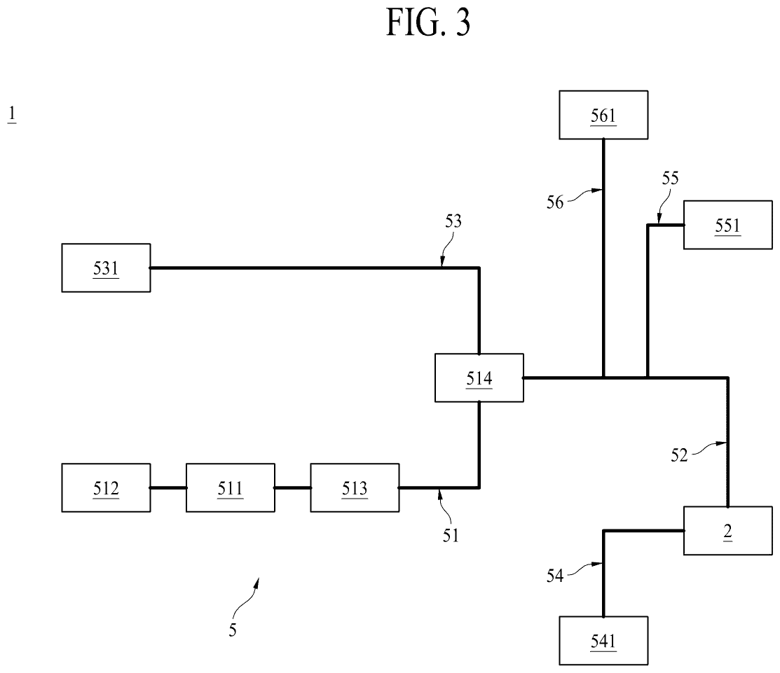

The substrate processing apparatus 1 may include a fourth source line 56 (illustrated in FIG. 3).

The fourth source line 56 may connect a third source carrier supply unit 561 (illustrated in FIG. 3) to the second source line 52. One side of the fourth source line 56 may be connected to the third source carrier supply unit 561, and the other side may be connected to the second source line 52, between the vaporizer 514 and the first source purge line 55. The fourth source line 56 may be implemented with a pipe, a hose, or a hole of a gas block. The third source carrier supply unit 561 may supply a third source carrier gas to the second source line 52 through the fourth source line 56. The third source carrier gas may be supplied to the second source line 52 and may then flow along the second source line 52 and may be supplied into the chamber 2.

As described above, the gas supply method of the substrate processing apparatus according to the present inventive concept may be performed by using the substrate processing apparatus 1. The gas supply method of the substrate processing apparatus according to the present inventive concept may supply a gas into the chamber 2 so that the substrate processing apparatus 1 performs an atomic layer deposition process.

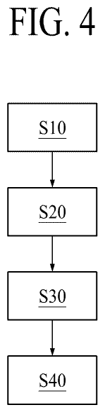

Referring to FIGS. 1 to 4, the gas supply method of the substrate processing apparatus according to the present inventive concept may include a first step S10, a second step S20, a third step S30, and a fourth step S40.

The first step S10 may be performed by supplying the first source carrier gas from the first source carrier supply unit 512 to the source storage unit 511 to supply the source of the source storage unit 511 at a certain flow rate through the Mass Flow Controller 513. In this case, the first source carrier gas and the source may flow through the first source line 51.

The second step S20 may be performed by vaporizing the source supplied via the Mass Flow Controller 513 from the source storage unit 511 by using the vaporizer 514, based on the second source carrier gas supplied from the second source carrier supply unit 531 to the vaporizer 514. In this case, the second source carrier gas may be supplied from the second source carrier supply unit 531 to the vaporizer 514 through the third source line 53. The supply of the second source carrier gas and the supply of the source on the vaporizer 514 may be performed in parallel.

The third step S30 may be performed by supplying the source, vaporized by the vaporizer 514, to the chamber 2 through the second source line 52. In this case, the source vaporized by the vaporizer 514 may be injected through the injection unit 4 toward the substrate 100 supported by the substrate supporting unit 3. Accordingly, a processing process using the source may be performed on the substrate 100 disposed in the chamber 2.

The fourth step S40 may be performed by stopping the supply of the source of the source storage unit 511 on the vaporizer 514 and supplying the second source carrier gas to the vaporizer 514. Accordingly, in a state where the supply of the source of the source storage unit 511 is stopped, the second source carrier gas may be supplied to the chamber 2 through the second source line 52 via the vaporizer 514.

As described above, the gas supply method of the substrate processing apparatus according to the present inventive concept is implemented to increase a transfer force for transferring the source to the chamber 2 by using the first source carrier gas of the first source carrier supply unit 512 and the second source carrier gas of the second source carrier supply unit 531. Accordingly, the gas supply method of the substrate processing apparatus according to the present inventive concept may realize the following effects.

The gas supply method of the substrate processing apparatus according to the present inventive concept may increase the amount of supply of a high-viscosity source supplied to the chamber 2 even when the high-viscosity source is supplied to the chamber 2. Accordingly, the gas supply method of the substrate processing apparatus according to the present inventive concept may contribute to enhance the stability of the processing process by using a high-viscosity source and may contribute to enhance the quality of the substrate 100 on which the processing process has been performed by using a high-viscosity source. Also, the gas supply method of the substrate processing apparatus according to the present inventive concept may decrease a deviation of the amount of supply of the high-viscosity source supplied to the chamber 2, and thus, may contribute to enhance process reproducibility. For example, the gas supply method of the substrate processing apparatus according to the present inventive concept may supply the chamber 2 with a high-viscosity source including at least one of lanthanum (La), gadolinium (Gd), and yttrium (Y).

The gas supply method of the substrate processing apparatus according to the present inventive concept may be possible to supply a high-viscosity source to the chamber 2 in an undiluted state. Accordingly, the gas supply method of the substrate processing apparatus according to the present inventive concept may contribute to enhance a process rate such as a deposition rate in performing the processing process, and thus, may contribute to enhance the productivity of the substrate 100 on which the processing process has been performed.

The gas supply method of the substrate processing apparatus according to the present inventive concept may decrease a flow rate difference between a high-viscosity source supplied from the source storage unit 511 and a high-viscosity source supplied from the chamber 2. That is, the gas supply method of the substrate processing apparatus according to the present inventive concept may decrease the amount of loss of a high-viscosity source which is not used in the processing process and is lost. Accordingly, the gas supply method of the substrate processing apparatus according to the present inventive concept may contribute to reduce the process cost for performing the processing process.

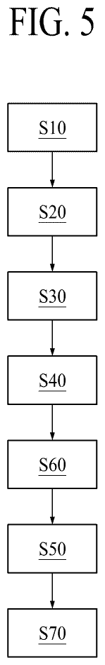

Referring to FIGS. 1 to 5, the gas supply method of the substrate processing apparatus according to the present inventive concept may include a fifth step S50.

The fifth step S50 may be performed by supplying a reactant gas to the chamber 2 after the fourth step S40. The fifth step S50 may be performed by supplying the reactant gas to the chamber 2 through the reactant line 54 by using the reactant supply unit 541. In this case, the reactant gas may be injected through the injection unit 4 toward the substrate 100 supported by the substrate supporting unit 3. Therefore, a processing process using the reactant gas may be performed on the substrate 100 disposed in the chamber 2. The fifth step S50 may be performed after the supply of the source of the source storage unit 511 is stopped through the fourth step S40, and then, the source and the reactant gas may be sequentially suppled into the chamber 2. Accordingly, a processing process of depositing a thin film on the substrate 100 may be performed by an atomic layer deposition process in the chamber 2. In a case where the source includes at least one of lanthanum (La), gadolinium (Gd), and yttrium (Y), the reactant gas may include at least one of oxygen (O₂), ozone (O₃), and nitrogen dioxide (NO₂).

Referring to FIGS. 1 to 5, the gas supply method of the substrate processing apparatus according to the present inventive concept may include a first purge step S60.

The first purge step S60 may be performed by supplying the first source purge gas to the chamber 2 through the first source purge line 55 by using the first source purge supply unit 551. In this case, the first source purge gas may be supplied to the chamber 2 through the second source line 52 after being supplied from the first source purge line 55 to the second source line 52. The first purge step S60 may be performed after the fourth step S40. Accordingly, after the fourth step S40, the source which is not used in the processing process may be purged to the outside of the chamber 2 by the first source purge gas which is supplied to the chamber 2 through the first purge step S60.

Referring to FIGS. 1 to 5, the gas supply method of the substrate processing apparatus according to the present inventive concept may include a second purge step S70.

The second purge step S70 may be performed by supplying the first source purge gas to the chamber 2 through the first source purge line 55 by using the first source purge supply unit 551. The second purge step S70 may be performed after the fifth step S50. Accordingly, after the fifth step S50, the reactant gas which is not used in the processing process may be purged to the outside of the chamber 2 by the first source purge gas which is supplied to the chamber 2 through the second purge step S70.

Here, the fourth step S40 may be performed by stopping the supply of the source of the source storage unit 511 on the vaporizer 514 and supplying the third source carrier gas to the third source carrier supply unit 561. In this case, in the embodiment described above, the fourth step S40 may be performed by supplying the third source carrier gas to the second source line 52, instead of supplying the second source carrier gas to the vaporizer 514. Accordingly, in a state where the supply of the source of the source storage unit 511 is stopped, the third source carrier gas may be supplied to the chamber 2 through the second source line 52 after being supplied to the second source line 52 between the vaporizer 514 and the first source purge line 55.

As described above, the gas supply method of the substrate processing apparatus according to the present inventive concept is implemented to increase a transfer force for transferring the source to the chamber 2 by using the first source carrier gas, the second source carrier gas, and the third source carrier gas. Accordingly, the gas supply method of the substrate processing apparatus according to the present inventive concept may realize the following effects.

The gas supply method of the substrate processing apparatus according to the present inventive concept may increase the amount of supply of a high-viscosity source supplied to the chamber 2 by using the first source carrier gas, the second source carrier gas, and the third source carrier gas, and thus, may contribute to enhance the stability of the processing process using a high-viscosity source and the quality of the substrate 100 on which the processing process has been performed. Also, the gas supply method of the substrate processing apparatus according to the present inventive concept may decrease a deviation of the amount of supply of a high-viscosity source supplied to the chamber 2 by using the first source carrier gas, the second source carrier gas, and the third source carrier gas, and thus, may enhance process reproducibility.

The gas supply method of the substrate processing apparatus according to the present inventive concept may be possible to supply a high-viscosity source to the chamber 2 in an undiluted state by using the first source carrier gas, the second source carrier gas, and the third source carrier gas. Accordingly, the gas supply method of the substrate processing apparatus according to the present inventive concept may contribute to enhance a process rate such as a deposition rate in performing the processing process, and thus, may contribute to increase the productivity of the substrate 100 on which the processing process has been performed.

The gas supply method of the substrate processing apparatus according to the present inventive concept may decrease a flow rate difference between a high-viscosity source supplied from the source storage unit 511 and a high-viscosity source supplied from the chamber 2 by using the first source carrier gas, the second source carrier gas, and the third source carrier gas. That is, the gas supply method of the substrate processing apparatus according to the present inventive concept may decrease the amount of loss of a high-viscosity source which is not used in the processing process and is lost. Accordingly, the gas supply method of the substrate processing apparatus according to the present inventive concept may contribute to reduce the process cost for performing the processing process.

In the gas supply method of the substrate processing apparatus according to the present inventive concept, at least one of the first source carrier gas, the second source carrier gas, and the third source carrier gas may include an inert gas. In this case, at least one of the first source carrier gas, the second source carrier gas, and the third source carrier gas may not affect the processing process. For example, at least one of the first source carrier gas, the second source carrier gas, and the third source carrier gas may include at least one of argon (Ar) and nitrogen (N₂).

In the gas supply method of the substrate processing apparatus according to the present inventive concept, a flow rate of at least one of the first source carrier gas, the second source carrier gas, and the third source carrier gas may be less than a flow rate of the first source purge gas. Accordingly, the gas supply method of the substrate processing apparatus according to the present inventive concept may increase the amount of supply the source supplied to the chamber 2 by using the first source carrier gas, the second source carrier gas, and the third source carrier gas and may prevent an excessive increase in internal pressure of the chamber 2.

In the gas supply method of the substrate processing apparatus according to the present inventive concept, the second source carrier gas may be a gas which assists the vaporization of the source in the vaporizer 514. Accordingly, the second source carrier gas may increase a vaporization rate of the source in the vaporizer 514 and may also be used to increase the amount of supply of a source which is vaporized by the vaporizer 514 and is supplied to the chamber 2.

In the gas supply method of the substrate processing apparatus according to the present inventive concept, a sum time which is a sum of a performance time of the first step S10, a performance time of the second step S20, and a performance time of the third step S30 may be equal to a performance time of the fourth step S40 or may be shorter than the performance time of the fourth step S40. That is, the performance time of the fourth step S40 may be equal to the sum time or may be longer than the sum time. Accordingly, the gas supply method of the substrate processing apparatus according to the present inventive concept may supply the second source carrier gas or the third source carrier gas to the chamber 2 for a relatively long time in a state where the supply of the source of the source storage unit 511 is stopped, and thus, may more decrease the amount of loss of a high-viscosity source which is not used in the processing process and is lost, thereby contributing to more reduce the process cost for performing the processing process.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A gas supply method of supplying a gas into a chamber for performing an atomic layer deposition (ALD) process in a substrate processing apparatus including: a first source line connecting a source storage unit, a first source carrier supply unit, a Mass Flow Controller, and a vaporizer with one another, a second source line connecting the vaporizer to the chamber; and a third source line connecting the vaporizer to a second source carrier supply unit, the gas supply method comprising:
a first step of supplying a first source carrier gas from the first source carrier supply unit to the source storage unit to supply a source of the source storage unit to the vaporizer at a certain flow rate through the Mass Flow Controller;
a second step of vaporizing the source supplied via the Mass Flow Controller from the source storage unit by using the vaporizer, based on a second source carrier gas supplied from the second source carrier supply unit to the vaporizer;
a third step of supplying the source, vaporized by the vaporizer, to the chamber through the second source line; and
a fourth step of stopping supply of the source of the source storage unit on the vaporizer and supplying the second source carrier gas to the vaporizer.

2. The gas supply method of claim 1, comprising a fifth step of supplying a reactant gas to the chamber after the fourth step.

3. The gas supply method of claim 1, comprising a first purge step of supplying a first source purge gas to the chamber through a first source purge line by using a first source purge supply unit connected to the second source line,
wherein the first purge step is performed after the fourth step.

4. The gas supply method of claim 2, comprising a second purge step of supplying a first source purge gas to the chamber through a first source purge line by using a first source purge supply unit connected to the second source line,
wherein the second purge step is performed after the fifth step.

5. A gas supply method of supplying a gas into a chamber for performing an atomic layer deposition (ALD) process in a substrate processing apparatus including: a first source line connecting a source storage unit, a first source carrier supply unit, a Mass Flow Controller, and a vaporizer with one another, a second source line connected to a first source purge line connected to a first source purge supply unit and connecting the vaporizer to the chamber; a third source line connecting the vaporizer to a second source carrier supply unit; and a third source carrier supply unit connected to the second source line between the vaporizer and the first source purge line, the gas supply method comprising:
a first step of supplying a first source carrier gas from the first source carrier supply unit to the source storage unit to supply a source of the source storage unit to the vaporizer at a certain flow rate through the Mass Flow Controller;
a second step of vaporizing the source supplied via the Mass Flow Controller from the source storage unit by using the vaporizer, based on a second source carrier gas supplied from the second source carrier supply unit to the vaporizer;
a third step of supplying the source, vaporized by the vaporizer, to the chamber through the second source line; and
a fourth step of stopping supply of the source of the source storage unit on the vaporizer and supplying a third source carrier gas to the second source line between the vaporizer and the first source purge line by using the third source carrier supply unit.

6. The gas supply method of claim 5, comprising a fifth step of supplying a reactant gas to the chamber after the fourth step.

7. The gas supply method of claim 5, comprising a first purge step of supplying a first source purge gas to the second source line by using the first source purge supply unit after the fourth step.

8. The gas supply method of claim 5, wherein at least one of the first source carrier gas, the second source carrier gas, and the third source carrier gas comprises an inert gas.

9. The gas supply method of claim 5, wherein a flow rate of at least one of the first source carrier gas, the second source carrier gas, and the third source carrier gas is less than a flow rate of the first source purge gas supplied by the first source purge supply unit.

10. The gas supply method of claim 1, wherein the second source carrier gas is a gas assisting vaporization of the source in the vaporizer.

11. The gas supply method of claim 1, wherein a sum time which is a sum of a performance time of the first step, a performance time of the second step, and a performance time of the third step is equal to a performance time of the fourth step, or is shorter than the performance time of the fourth step.
